(19) United States
(12) Patent Application Publication
(10) Pub. No.: US 2026/0143630 A1
(43) Pub. Date: May 21, 2026

(54) PUMP PACK ASSEMBLY IN A CLOSED LOOP SOLUTION

(71) Applicant: Lenovo Global Technology (United States) Inc., Morrisville, NC (US)

(72) Inventors: Arvind Modekurti, Cary, NC (US); Bejoy J Kochuparambil, Apex, NC (US); Vinod Kamath, Raleigh, NC (US)

(21) Appl. No.: 18/954,874

(22) Filed: Nov. 21, 2024

(51) Int. Cl. H05K 7/20

(52) U.S. Cl. CPC H05K 7/20272; H05K 7/20154; H05K 7/20263; H05K 7/20772

(57) ABSTRACT

An apparatus with computing device cooling system with a replaceable pump assembly includes a pump assembly configured to connect to a cooling system within a rack-mountable computing device. The rack-mountable computing device includes a plurality of data processing devices within the rack-mountable computing device. The plurality of data processing devices are cooled by cooling fluid from the cooling system. The apparatus includes two or more pumps mounted to the pump assembly, a fluid inlet connector, a fluid outlet connector, and a fluid channel extending from the fluid inlet connector, through each of the two or more pumps in a series connection, and to the fluid outlet connector.

### FIELD

The subject matter disclosed herein relates to computing device cooling systems and more particularly relates to a replaceable pump pack assembly for a computing device cooling system.

### BACKGROUND

Computing devices are evolving to draw more power. Higher power computing devices often require fluid cooling systems.

### BRIEF SUMMARY

An apparatus with a computing device cooling system with a replaceable pump assembly includes a pump assembly configured to connect to and disconnect from a cooling system within a rack-mountable computing device. The rack-mountable computing device includes a plurality of data processing devices within the rack-mountable computing device. The plurality of data processing devices are cooled by cooling fluid from the cooling system. The apparatus includes two or more pumps mounted to the pump assembly, a fluid inlet connector, a fluid outlet connector, and a fluid channel extending from the fluid inlet connector, through each of the two or more pumps in a series connection, and to the fluid outlet connector.

Another apparatus with a computing device cooling system with a replaceable pump assembly that includes a pump assembly configured to connect to and disconnect from a cooling system within a rack-mountable computing device. The rack-mountable computing device includes a plurality of data processing devices within the rack-mountable computing device. The plurality of data processing devices are cooled by cooling fluid from the cooling system. The apparatus includes two or more pumps mounted to the pump assembly, a quick-disconnect fluid inlet connector, a quick-disconnect fluid outlet connector, and a fluid channel extending from the quick-disconnect fluid inlet connector, through each of the two or more pumps in a series connection, and to the quick-disconnect fluid outlet connector. Each of the two or more pumps includes a clutch between an impeller of pump and a rotor of the pump.

A rack-mountable computing device includes a plurality of data processing devices and a cooling system configured to provide cooling to the plurality of data processing devices via cooling fluid loops. The cooling system includes a pump assembly configured to mount to the cooling system. The pump assembly includes two or more pumps mounted to the pump assembly, a fluid inlet connector, a fluid outlet connector, and a fluid channel extending from the fluid inlet connector, through each of the two or more pumps in a series connection, and to the fluid outlet connector.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1A is a schematic block diagram illustrating a computing device cooling system with a replaceable pump assembly, according to various embodiments;

FIG. 1B is a schematic block diagram illustrating another computing device cooling system with two replaceable pump assemblies, according to various embodiments;

FIG. 2 is a schematic block diagram illustrating a replaceable pump assembly with a bypass loop, according to various embodiments;

FIG. 3 is a schematic block diagram illustrating a pump with a freewheeling clutch, according to various embodiments; and

FIG. 4 is a schematic block diagram illustrating a pump with a magnetic clutch, according to various embodiments.

### DETAILED DESCRIPTION

As will be appreciated by one skilled in the art, aspects of the embodiments may be embodied as a system, method or program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a program product embodied in one or more computer readable storage devices storing machine readable code, computer readable code, and/or program code, referred hereafter as code. The storage devices, in some embodiments, are tangible, non-transitory, and/or non-transmission.

Many of the functional units described in this specification have been labeled as modules, in order to more particularly emphasize their implementation independence. For example, a module may be implemented as a hardware circuit comprising custom very large scale integrated (“VLSI”) circuits or gate arrays, off-the-shelf semiconductors such as logic chips, transistors, or other discrete components. A module may also be implemented in programmable hardware devices such as a field programmable gate array (“FPGA”), programmable array logic, programmable logic devices or the like.

Modules may also be implemented in code and/or software for execution by various types of processors. An identified module of code may, for instance, comprise one or more physical or logical blocks of executable code which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different computer readable storage devices. Where a module or portions of a module are implemented in software, the software portions are stored on one or more computer readable storage devices.

Any combination of one or more computer readable medium may be utilized. The computer readable medium may be a computer readable storage medium. The computer readable storage medium may be a storage device storing the code. The storage device may be, for example, but not limited to, an electronic, magnetic, optical, electromagnetic, infrared, holographic, micromechanical, or semiconductor system, apparatus, or device, or any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

More specific examples (a non-exhaustive list) of the storage device would include the following: an electrical connection having one or more wires, a portable computer diskette, a hard disk, a random access memory (“RAM”), a read-only memory (“ROM”), an erasable programmable read-only memory (“EPROM” or Flash memory), a portable compact disc read-only memory (“CD-ROM”), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Code for carrying out operations for embodiments may be written in any combination of one or more programming languages including an object oriented programming language such as Python, Ruby, R, Java, Java Script, Smalltalk, C++, C sharp, Lisp, Clojure, PHP, or the like, and conventional procedural programming languages, such as the “C” programming language, or the like, and/or machine languages such as assembly languages. The code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (“LAN”) or a wide area network (“WAN”), or the connection may be made to an external computer (for example, through the Internet using an Internet Service Provider).

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, systems, and program products according to embodiments. It will be understood that each block of the schematic flowchart diagrams and/or schematic block diagrams, and combinations of blocks in the schematic flowchart diagrams and/or schematic block diagrams, can be implemented by code. This code may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The code may also be stored in a storage device that can direct a computer, other programmable data processing apparatus, or other devices to function in a particular manner, such that the instructions stored in the storage device produce an article of manufacture including instructions which implement the function/act specified in the schematic flowchart diagrams and/or schematic block diagrams block or blocks.

The code may also be loaded onto a computer, other programmable data processing apparatus, or other devices to cause a series of operational steps to be performed on the computer, other programmable apparatus or other devices to produce a computer implemented process such that the code which execute on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and program products according to various embodiments. In this regard, each block in the schematic flowchart diagrams and/or schematic block diagrams may represent a module, segment, or portion of code, which comprises one or more executable instructions of the code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and code.

The description of elements in each figure may refer to elements of proceeding figures. Like numbers refer to like elements in all figures, including alternate embodiments of like elements.

As used herein, a list with a conjunction of “and/or” includes any single item in the list or a combination of items in the list. For example, a list of A, B and/or C includes only A, only B, only C, a combination of A and B, a combination of B and C, a combination of A and C or a combination of A, B and C. As used herein, a list using the terminology “one or more of” includes any single item in the list or a combination of items in the list. For example, one or more of A, B and C includes only A, only B, only C, a combination of A and B, a combination of B and C, a combination of A and C or a combination of A, B and C. As used herein, a list using the terminology “one of” includes one and only one of any single item in the list. For example, “one of A, B and C” includes only A, only B or only C and excludes combinations of A, B and C.

An apparatus with a computing device cooling system with a replaceable pump assembly includes a pump assembly configured to connect to and disconnect from a cooling system within a rack-mountable computing device. The rack-mountable computing device includes a plurality of data processing devices within the rack-mountable computing device. The plurality of data processing devices are cooled by cooling fluid from the cooling system. The apparatus includes two or more pumps mounted to the pump assembly, a fluid inlet connector, a fluid outlet connector, and a fluid channel extending from the fluid inlet connector, through each of the two or more pumps in a series connection, and to the fluid outlet connector.

In some embodiments, the fluid inlet connector and the fluid outlet connector are quick disconnect-type connectors. In other embodiments, he quick disconnect-type connectors are configured to block cooling fluid from exiting from the pump assembly and/or the cooling system when in a disconnected condition and to allow cooling fluid to flow through the quick disconnect-type connectors when connected. In other embodiments, the pump assembly with the two or more pumps is configured to be removable from the cooling system of the rack-mountable computing device and to be replaceable with another pump assembly with an additional two or more pumps.

In other embodiments, each of the two or more pumps includes a clutch between an impeller of pump and a rotor of the pump. In other embodiments, the clutch of each of the two or more pumps is configured to allow the impeller of a failed pump of the two or more pumps to continue to rotate in a pump direction consistent with pumping of cooling fluid through the two or more pumps while the rotor of the pump is stopped and/or rotating slower than the impeller and to rotate the impeller in the pump direction of a pump of the two or more pumps to pump the cooling fluid through the impeller in response to the pump moving the rotor in the pump direction. In other embodiments, the clutch includes a freewheeling clutch with a one-way gear. In other embodiments, the clutch includes a magnetic clutch configured to allow the impeller to rotate in a pump direction independent of a pump motor during a pump failure and to rotate in the pump direction with the pump motor during a non-failure condition.

In some embodiments, the fluid channel and the two or more pumps are filled with a coolant prior to connection to the cooling system. In other embodiments, the plurality of data processing devices include a plurality of accelerators, a plurality of graphical processing units (“GPUs”), or a plurality of processors. In other embodiments, the plurality of data processing devices include cooling requirements that exceed air flow capabilities of air directed next to the plurality of data processing devices. In other embodiments, the rack-mountable computing device includes a heat exchanger and one or more fans directing air flow across the heat exchanger, where the two or more pumps are in fluid communication with the heat exchanger. In other embodiments, the apparatus includes a pump failure module configured to detect a pump failure and to transmit a pump failure alert in response to the pump failure. In other embodiments, each of the two or more pumps includes a bypass loop. The bypass loop of a pump of the two or more pumps is configured for cooling fluid fed to and coming from the pump to bypass the pump. The bypass loop includes a pressure relief valve.

An apparatus with a computing device cooling system with a replaceable pump assembly that includes a pump assembly configured to connect to and disconnect from a cooling system within a rack-mountable computing device. The rack-mountable computing device includes a plurality of data processing devices within the rack-mountable computing device. The plurality of data processing devices are cooled by cooling fluid from the cooling system. The apparatus includes two or more pumps mounted to the pump assembly, a quick-disconnect fluid inlet connector, a quick-disconnect fluid outlet connector, and a fluid channel extending from the quick-disconnect fluid inlet connector, through each of the two or more pumps in a series connection, and to the quick-disconnect fluid outlet connector. Each of the two or more pumps includes a clutch between an impeller of pump and a rotor of the pump.

In some embodiments, the pump assembly with the two or more pumps is configured to be removable from the cooling system of the rack-mountable computing device and to be replaceable with another pump assembly with an additional two or more pumps. In other embodiments, the clutch of each of the two or more pumps is configured to allow the impeller of a failed pump of the two or more pumps to continue to rotate in a pump direction consistent with pumping of cooling fluid through the two or more pumps while the rotor of the pump is stopped and/or rotating slower than the impeller and to rotate the impeller in the pump direction of a pump of the two or more pumps to pump the cooling fluid through the impeller in response to the pump moving the rotor in the pump direction. In other embodiments, the rack-mountable computing device includes a heat exchanger and one or more fans directing air flow across the heat exchanger. The two or more pumps are in fluid communication with the heat exchanger.

A rack-mountable computing device includes a plurality of data processing devices and a cooling system configured to provide cooling to the plurality of data processing devices via cooling fluid loops. The cooling system includes a pump assembly configured to mount to the cooling system. The pump assembly includes two or more pumps mounted to the pump assembly, a fluid inlet connector, a fluid outlet connector, and a fluid channel extending from the fluid inlet connector, through each of the two or more pumps in a series connection, and to the fluid outlet connector.

In some embodiments, the rack-mountable computing device includes a heat exchanger within the cooling system, and one or more fans within the cooling system. The one or more fans direct air flow across the heat exchanger. The two or more pumps are in fluid communication with the heat exchanger.

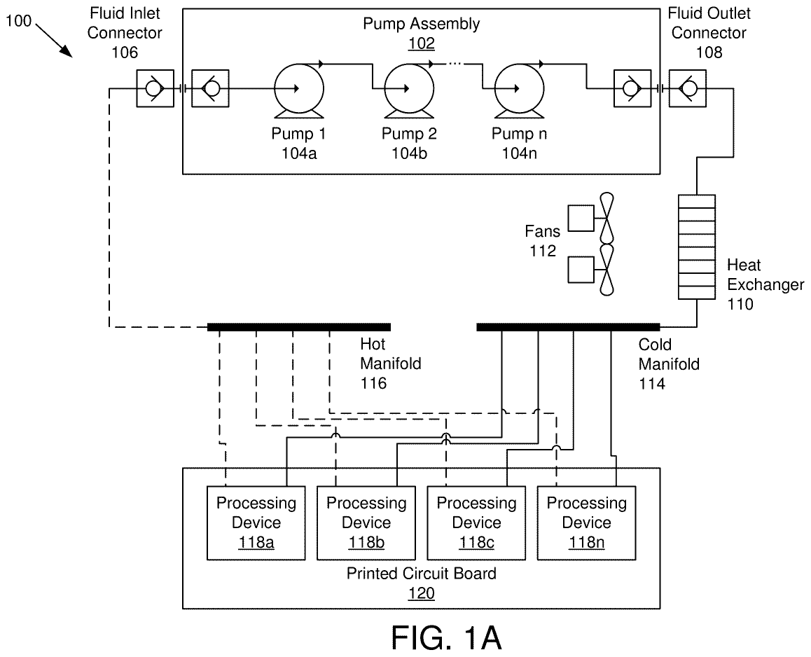

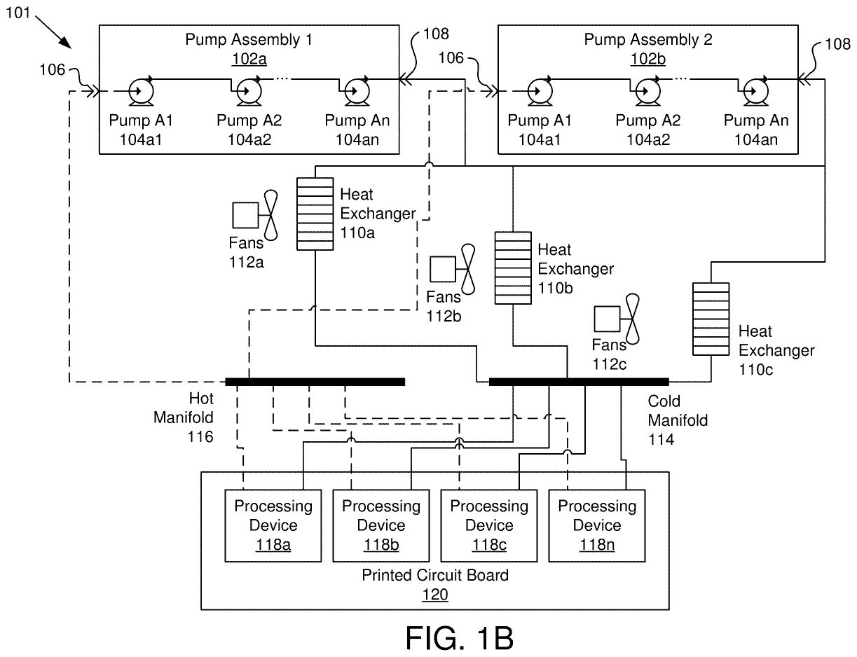

FIG. 1A is a schematic block diagram illustrating a computing device cooling system 100 with a replaceable pump assembly 102, according to various embodiments. The computing device cooling system 100 includes a pump assembly 102 with n pumps 104a-104n (generically or collectively “104”), where at least some of which are connected in series. As used herein, pumps 104a-104n connected in series includes a single fluid channel entering and exiting a first pump 104a then entering and exiting a second pump 104b, and so on to a last pump 104n so that there is a continuous fluid pathway extending through the pumps 104. In particular, the series-connected pumps 104 are not connected in parallel with a fluid pathway that splits to feed the pumps 104. However, in alternate embodiments, the pump assembly 102 includes two or more groupings of series connected pumps 104 where each grouping includes two or more pumps 104 connected in series. FIG. 1A depicts a single grouping of n pumps 104 connected in series.

Each pump assembly 102 includes a fluid inlet connector 106 and a fluid outlet connector 108. The fluid inlet connector 106 and the fluid outlet connector 108 each connect to and disconnect from a matching fluid connector that is connected to cooling channels that may include pipes, tubing, etc. configured to transport cooling fluid. In some embodiments, the fluid inlet connector 106 and/or the fluid outlet connector 108 are quick disconnect-type connectors. In some embodiments, the quick disconnect-type connectors allow connection and disconnection without cooling fluid freely running out of the pump assembly 102 and cooling channels connected to the pump assembly 102. In some embodiments, the quick disconnect-type connectors are configured to block cooling fluid from exiting from the pump assembly 102 and/or the cooling system 100 when in a disconnected condition and to allow cooling fluid to flow through the quick disconnect-type connectors when connected. In some embodiments, the pump assembly 102 is pre-loaded with cooling fluid so that replacement of a failed pump assembly 102 is able to begin pumping without filling the pump assembly 102 with cooling fluid, without purging a significant amount of air from the cooling channels, etc.

In some embodiments, the cooling fluid is water. In other embodiments, the cooling fluid is glycol, a mineral oil, a synthetic oil, a fluorocarbon, a dielectric fluid, or the like. In some embodiments, the cooling system 100 is a single-phase cooling system 100 meaning that the cooling fluid stays in one state through a cooling cycle, such as in a liquid state. In other embodiments, the cooling system 100 is a two-phase cooling system, meaning that the cooling fluid transitions between two states, such as liquid and gas, through the cooling cycle.

In some embodiments, the cooling system 100 includes a heat exchanger 110. In some embodiments, the heat exchanger 110 receives hot cooling fluid and outputs cooling fluid that has a lower temperature than the temperature of the hot cooling fluid that is input. As the cooling fluid travels through the heat exchanger 110, heat from the cooling fluid is transferred to the structure of the heat exchanger 110, which is transferred to air passing through the heat exchanger 110. In some embodiments, the cooling system 100 includes fans 112 that push air through the heat exchanger 110 to remove heat from the heat exchanger 110. In some embodiments, air flows into a first side of the computing device, through the fans 112, through the heat exchanger 110, and exits a second side of the computing device. In some embodiments, channels in the computing device guide air through the fans 112 and heat exchangers 110. The fans 112 are typically connected to a power supply (not shown) in the computing device and are controlled by a baseboard management controller (“BMC”)(not shown) or other controller within the computing device. In some embodiments, the heat exchanger 110 and fans 112 are in a single unit, which may be called a chiller, a compressor, or the like. In other embodiments, the heat exchanger is connected to a second cooling loop that extends externally to the computing device and the second cooling loop removes heat from the heat exchanger 110.

The cooling system 100 of FIG. 1A includes a cold manifold 114 and cooling fluid from the heat exchanger 110 runs to the cold manifold 114 and is split into various pathways to feed processing devices 118a-118n (generically or collectively “118”) on a printed circuit board 120. While a single printed circuit board 120 is depicted, other embodiments include multiple printed circuit boards 120. The cooling fluid picks up heat from the processing devices 118 and exits cooling lines (depicted as dashed lines) running to a hot manifold 116. The cooling fluid from the various processing devices 118 is collected at the hot manifold 116 and exits in a single cooling line running to the fluid inlet connector 106 of the pump assembly 102. While a single cold manifold 114 and a single hot manifold 116 are depicted, one of skill in the art will recognize that the cooling lines may be split and gathered in other ways, such as simple Y-connectors, T-connectors, or the like. In other embodiments, the cooling system 100 includes multiple cold manifolds 114 and/or hot manifolds 116.

The pumps 104 of the pump assembly 102 are configured for redundancy and are sized and configured for at least one pump (e.g., 104a) to fail. In some examples, there are three pumps 104a, 104b, 104c and the pump assembly 102 has pumps 104 sized and configured for one of the three pumps 104 to fail. In such embodiments, the pumps 104 are oversized so that two of the pumps (e.g., 104b, 104c) are able to handle the pumping load of the cooling fluid when the first pump 104a has failed. As will be understood by one of skill in the art, any of the pumps 104 of the pump assembly 102 may fail and the other pumps 104 are sized to handle the pump load. In other embodiments, the pumps 104 are all sized so that two of three pumps (e.g., 104a, 104b) may fail while a third pump 104c is configured to continue to operate.

For the pump assembly 102 to have a pump 104 fail, the pumps 104 are configured to have the cooling fluid continue through the pumps 104. In some embodiments, the pumps 104 are configured for the impeller of the pumps 104 to continue to rotate after a pump 104 has failed. In some embodiments, the impeller is rigidly connected to pump motor, which spins when the pump 104 has failed. In some embodiments, the pump motor is configured to have minimal resistance so that the impeller of the pump 104 is able to spin when the pump 104 is not providing power to the impeller.

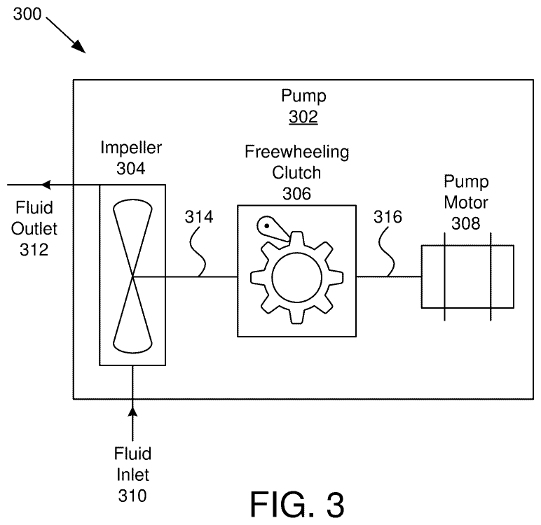

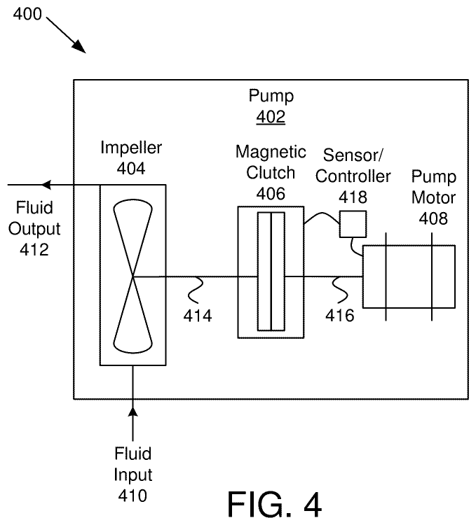

In other embodiments, the impeller is connected to the motor via a clutch that allows the impeller to continue to spin independently from a shaft of the motor. In some embodiments, the clutch disconnects the impeller from the pump motor. In other embodiments, the clutch has a freewheeling mechanism to allow the impeller to spin while the shaft of the pump motor is stopped. Various clutch assemblies are discussed further with respect to FIGS. 3 and 4.

In some embodiments, the pump assembly 102 is mounted on a frame of a standard size to allow exchanging one pump assembly 102 for another quickly. In some embodiments, the frame of the pump assembly 102 includes fastener points that mate with the computing device to allow quick exchange of pump assemblies 102. Typically, the pump assembly 102 also includes electrical connections for power and control of the pumps 104. In some embodiments, the electrical connections include a disconnect of a particular type and configuration so that each pump assembly 102 is compatible with an electrical connector of the computing device.

The computing device, in some embodiments, is rack-mountable to be mounted in racks that are used to mount computing devices and equipment. In some embodiments, the racks are standard width racks used in datacenters and other locations to house computing equipment. In some embodiments, the computing device includes processing devices 118 that require cooling via a cooling system 100. The pump assembly 102 with the two or more pumps 104 is configured to be removable from the cooling system 100 of the rack-mountable computing device and to be replaceable with another pump assembly 102 with an additional two or more pumps 104.

The processing devices 118, in various embodiments, include accelerators, processors, graphical processing units (“GPUs”), or the like. In current cloud computing systems, datacenters, and the like, often a server has remote processing capabilities. In some examples, it is more efficient for the server to send workloads to a GPU, accelerator, remote processor, or other processing device 118. The processing devices 118, over time, have become more powerful and generate a lot of heat. In some embodiments, the processing devices 118 are accelerators that consume 1 kilowatt (“kW”) of electrical power, which generate a tremendous amount of heat. The heat from several processing devices 118 on a printed circuit board 120 is typically too much for simple air cooling so that the data processing devices 118 have cooling requirements that exceed air flow capabilities of air directed next to the plurality of data processing devices 118. Thus, the heat is removed via a cooling fluid by the pumps 104 and the cooling fluid passes through the heat exchanger 110 where the fans 112 remove the heat via convection.

FIG. 1B is a schematic block diagram illustrating another computing device cooling system 101 with two replaceable pump assemblies 102, according to various embodiments. The cooling system 101 includes two pump assemblies 102a, 102b, which are substantially similar to the pump assembly 102 described with respect to the cooling system 100 of FIG. 1. The pump assemblies 102a, 102b are arranged in parallel and feed three heat exchangers 110a, 110b, 110c, which are each cooled by three sets of fans 112a, 112b, 112c. The heat exchangers 110a, 110b, 110c feed a cold manifold 114, which feeds processing devices 118 on a printed circuit board 120. Hot cooling fluid from the processing devices 118 are collected at a hot manifold 116. Two cooling lines from the hot manifold 116 go to the two pump assemblies 102a, 102b. The pump assemblies 102a, 102b each include a fluid inlet connector 106 and a fluid outlet connector 108. The fluid inlet connector 106, the fluid outlet connector 108, the heat exchangers 110a, 110b, 110c, fans 112a, 112b, 112c, cold manifold 114, hot manifold 116, processing devices 118, and printed circuit board are substantially similar to those described above in relation to the cooling system 100 of FIG. 1.

The cooling system 101 of FIG. 1B, in some embodiments, is deployed on a computing device where the heat exchangers 110a, 110b, 110c are separated vertically into three different tiers with the fans 112a, 112b, 112c each on a different tier. While a single fan 112 is depicted on each tier, in various embodiments, the cooling system 101 includes multiple fans 112 at each tier. In some embodiments, the pump assemblies 102a, 102b are each positioned on a tier for cooling of the clutch. Thus, the design spreads the heat load of the processing devices 118 vertically for the fans 112a, 112b, 112c and heat exchangers 110a, 110b, 110c to be able to remove the heat.

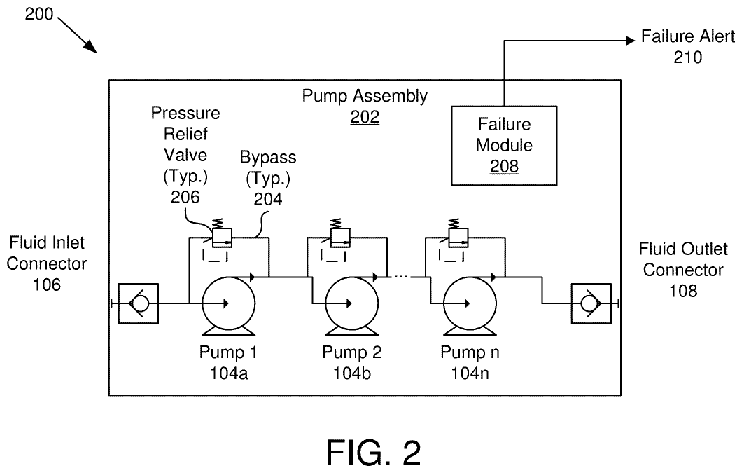

FIG. 2 is a schematic block diagram 200 illustrating a replaceable pump assembly 202 with a bypass loop 204, according to various embodiments. The pumps 104a, 104b, 104c, in some embodiments, are substantially similar to those described above in relation the cooling systems 100, 101 of FIGS. 1A, 1B. The bypass loops 204 are arranged so that each pump 104 includes a separate bypass loop 204, which enables fluid that would travel through the pump 104 to instead bypass the pump 104 when the pump 104 is stopped, broken, non-functional, etc.

In some embodiments, each bypass loop 204 includes a pressure relief valve 206, which is set at a particular bypass pressure. The bypass pressure is high enough so that when the pump 104 is operational, cooling fluid is fed into the impeller of the pump 104 and not through the bypass loop 204. If the pump 104 fails or stops, inlet pressure to the pump rises, for example due to forces associated with the pump motor transitioning to generate electricity. When the inlet pressure rises to the bypass pressure of the pressure relief valve 206, the pressure relief valve 206 opens and the cooling fluid that would normally past through the pump 104 instead goes through the bypass loop 204 and on to the next pump 104 or to the fluid outlet connector 108.

In some embodiments, the bypass loop 204 connects to the cooling lines leading to the pump 104 via a simple T-connection. In some embodiments, the pressure relief valve 206 has a selected bypass pressure setting that is adjustable. In other embodiments, the pressure relief valve 206 has a set bypass pressure setting. In some embodiments, the bypass pressure setting of the pressure relief valve 206 is chosen based on a known back pressure of the pump 104 when stopped and is selected to be just below the back pressure of the pump 104 to minimize pressure within the pump assembly 202. In other embodiments, the bypass pressure setting of the pressure relief valve 206 is chosen to be at a level anticipated for a catastrophic failure within the pump 104, such as when a bearing fails, an impeller blade fails and jambs the pump 104, or the like so that under other failure scenarios, such as the pump 104 losing power, the cooling fluid continues to go through the impeller of the pump 104 and only after more extreme failures does the cooling fluid pressure rise to the bypass pressure setting so that the cooling fluid goes through the bypass loop 204.

In some embodiments, the pump assembly 202, 102 includes a failure module 208 configured to transmit a failure alert 210 upon sensing failure of a pump 104. In some embodiments, the pump assembly 202, 102 includes one or more sensors connected to the failure module 208 that detect when a pump 104 has failed. When one or more sensors detect a failure, stoppage, etc. of a pump 104 of the pump assembly 102, a signal is sent to the failure module 208, which then sends a failure alert 210. For example, the sensors may include power sensors, pressure sensors, pump rotation sensors, and the like. In other embodiments, the failure module 208 is integrated with a pump controller located in the pump assembly 202, 102 or elsewhere and the pump controller senses a failure in a pump 104. The failure module 208 then receives, intercepts, etc. a signal from the pump controller indicative of a pump failure and the failure module 208 then transmits a failure alert 210. While the failure module 208 is depicted in the pump assembly 202, 102, in various embodiments all or a portion of the failure module 208 is located external to the pump assembly 202. In some embodiments, failure module 208 is part of a BMC of the computing device that includes the pump assembly 202, 102.

In various embodiments, the failure alert 210 includes a message that a pump 104 of the pump assembly 202, 102 has failed or is about to fail. In some embodiments, the failure alert 210 includes information about the pump assembly 202, 102, such as an identifier of the pump assembly 202, 102, an identifier of the computing device with the pump assembly 202, 102, an identifier of which pump 104 failed, or the like. In other embodiments, the failure alert 210 includes a timestamp of when the failure alert 210 was sent. In some embodiments, the failure module 208 transmits the failure alert 210 to a system administrator, to an owner of the computing device where the computing device is leased, to an on-site maintenance department, or the like. Beneficially, the failure module 208 transmitting a failure alert 210 provides information so that the pump assembly 202, 102 is able to be replaced.

FIG. 3 is a schematic block diagram 300 illustrating a pump 302 with a freewheeling clutch 306, according to various embodiments. The pump 302, in various embodiments, is substantially similar to those described above in relation to the cooling systems 100, 101 of FIGS. 1A and 1B and the pump assemblies 202, 102 of FIGS. 1A, 1B, and 2. The pump 302 includes an impeller 304, a freewheeling clutch 306, a pump motor 308, a fluid inlet 310, a fluid outlet 312, an impeller shaft 314, and a pump shaft 316. Other components, such as power wiring, control wiring, sensors, and the like are not depicted, but one of skill in the art will recognize other components that are present on the pump 302.

During normal operation, the pump motor 308 turns the pump shaft 316 in a pump direction, which is in a direction so that the freewheeling clutch 306 turns the impeller shaft 314, which turns the impeller 304, which then pumps cooling fluid into the fluid inlet 310, through the impeller 304, and out the fluid outlet 312. The freewheeling clutch 306 is configured so that when the pump motor 308 stops or rotates slower than during normal operation, the impeller shaft 314 and the impeller 304 continue to rotate in the pump direction due to the cooling fluid continuing to flow through the impeller 304 while the pump shaft 316 is stopped or slowed. In some embodiments, the freewheeling clutch 306 operates similar to a bicycle rear wheel that spins freely while not pedaling, but is able to lock when a user is pedaling to provide power to the wheel.

In some embodiments, the freewheeling clutch 306 includes a first portion connected to the pump shaft 316 that includes one or more latches that engage a gear of a second portion connected to the impeller shaft 316. The latches are configured with springs or a similar mechanism and are angled such that when the first portion spins with respect to the second portion in a first direction, the latches engage teeth on the gear and the first and second portions rotate together. When the first portion stops, the second portion and the gear continue to rotate and the latches are angled so that the latches do not engage the teeth of the gear and the impeller shaft 314 and impeller are allowed to continue to rotate independent of the pump shaft 316. One of skill in the art will recognize other designs of a freewheeling clutch 306 that would allow the impeller 304 to continue to turn when the pump motor 308 and pump shaft 316 has stopped.

FIG. 4 is a schematic block diagram 400 illustrating a pump 402 with a magnetic clutch 406, according to various embodiments. The pump 402, in various embodiments, is substantially similar to those described above in relation to the cooling systems 100, 101 of FIGS. 1A and 1B and the pump assemblies 202, 102 of FIGS. 1A, 1B, and 2. The pump 402 includes an impeller 404, a magnetic clutch 406, a pump motor 408, a fluid inlet 410, a fluid outlet 412, an impeller shaft 414, a pump shaft 416, and a sensor/controller 418. Other components, such as power wiring, control wiring, sensors, and the like are not depicted, but one of skill in the art will recognize other components that are present on the pump 402.

During normal operation, the magnetic clutch 406 is engaged and the pump motor 408 turns the pump shaft 416 in a pump direction, which also turns the impeller shaft 414, which turns the impeller 404, which then pumps cooling fluid into the fluid inlet 410, through the impeller 404, and out the fluid outlet 412. During the normal operation, the magnetic clutch 406 is energized so that the pump shaft 416 and the impeller shaft 414 rotate together in the pump direction.

The sensor/controller 418 is configured to de-energize the magnetic clutch 406 after sensing a failure in the pump 402, which decouples plates or other devices in the magnetic clutch 406 to allow the impeller shaft 414 and impeller 404 to continue to rotate in the pump direction while the pump shaft 416 has stopped or slowed. In some embodiments, the magnetic clutch 406 includes an electromagnet connected to the pump shaft 416 that connects to a metal plate connected to the impeller shaft 414 when energized, or vice-versa. One of skill in the art will recognize various magnetic clutch designs suitable for the pump 402.

The sensor/controller 418 provides power to the electromagnet during normal operation and stops power to the electromagnet in response to a pump failure. In various embodiments, the sensor/controller 418 is located in the pump 402, in the pump assembly 202, 102, in the computing device, in a BMC of the computing device, or other convenient location. Various sensors, controls, etc. may be used to detect a failure, as described above in relation to the failure module 208 of FIG. 2 to provide control signals to energize or de-energize the magnetic clutch 406.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
a pump assembly configured to connect to and disconnect from a cooling system within a rack-mountable computing device, the rack-mountable computing device comprising a plurality of data processing devices within the rack-mountable computing device, the plurality of data processing devices cooled by cooling fluid from the cooling system;
two or more pumps mounted to the pump assembly;
a fluid inlet connector;
a fluid outlet connector; and
a fluid channel extending from the fluid inlet connector, through each of the two or more pumps in a series connection, and to the fluid outlet connector.

2. The apparatus of claim 1, wherein the fluid inlet connector and the fluid outlet connector are quick disconnect-type connectors.

3. The apparatus of claim 2, wherein the quick disconnect-type connectors are configured to block cooling fluid from exiting from the pump assembly and/or the cooling system when in a disconnected condition and to allow cooling fluid to flow through the quick disconnect-type connectors when connected.

4. The apparatus of claim 1, wherein the pump assembly with the two or more pumps is configured to be removable from the cooling system of the rack-mountable computing device and to be replaceable with another pump assembly with an additional two or more pumps.

5. The apparatus of claim 1, wherein each of the two or more pumps comprises a clutch between an impeller of pump and a rotor of the pump.

6. The apparatus of claim 5, wherein the clutch of each of the two or more pumps is configured to allow the impeller of a failed pump of the two or more pumps to continue to rotate in a pump direction consistent with pumping of cooling fluid through the two or more pumps while the rotor of the pump is stopped and/or rotating slower than the impeller and to rotate the impeller in the pump direction of a pump of the two or more pumps to pump the cooling fluid through the impeller in response to the pump moving the rotor in the pump direction.

7. The apparatus of claim 5, wherein the clutch comprises a freewheeling clutch with a one-way gear.

8. The apparatus of claim 5, wherein the clutch comprises a magnetic clutch configured to allow the impeller to rotate in a pump direction independent of a pump motor during a pump failure and to rotate in the pump direction with the pump motor during a non-failure condition.

9. The apparatus of claim 1, wherein the fluid channel and the two or more pumps are filled with a coolant prior to connection to the cooling system.

10. The apparatus of claim 1, wherein the plurality of data processing devices comprise one of a plurality of accelerators, a plurality of graphical processing units (“GPUs”), and a plurality of processors.

11. The apparatus of claim 1, wherein the plurality of data processing devices comprise cooling requirements that exceed air flow capabilities of air directed next to the plurality of data processing devices.

12. The apparatus of claim 1, wherein the rack-mountable computing device comprises a heat exchanger and one or more fans directing air flow across the heat exchanger, wherein the two or more pumps are in fluid communication with the heat exchanger.

13. The apparatus of claim 1, further comprising a pump failure module configured to detect a pump failure and to transmit a pump failure alert in response to the pump failure.

14. The apparatus of claim 1, wherein each of the two or more pumps comprises a bypass loop, wherein the bypass loop of a pump of the two or more pumps is configured for cooling fluid fed to and coming from the pump to bypass the pump, the bypass loop comprising a pressure relief valve.

15. An apparatus comprising:
a pump assembly configured to connect to and disconnect from a cooling system within a rack-mountable computing device, the rack-mountable computing device comprising a plurality of data processing devices within the rack-mountable computing device, the plurality of data processing devices cooled by cooling fluid from the cooling system;
two or more pumps mounted to the pump assembly;
a quick-disconnect fluid inlet connector;
a quick-disconnect fluid outlet connector; and
a fluid channel extending from the quick-disconnect fluid inlet connector, through each of the two or more pumps in a series connection, and to the quick-disconnect fluid outlet connector,
wherein each of the two or more pumps comprises a clutch between an impeller of pump and a rotor of the pump.

16. The apparatus of claim 15, wherein the pump assembly with the two or more pumps is configured to be removable from the cooling system of the rack-mountable computing device and to be replaceable with another pump assembly with an additional two or more pumps.

17. The apparatus of claim 15, wherein the clutch of each of the two or more pumps is configured to allow the impeller of a failed pump of the two or more pumps to continue to rotate in a pump direction consistent with pumping of cooling fluid through the two or more pumps while the rotor of the failed pump is stopped and/or rotating slower than the impeller and to rotate the impeller in the pump direction of a pump of the two or more pumps to pump the cooling fluid through the impeller in response to the pump moving the rotor in the pump direction.

18. The apparatus of claim 15, wherein the rack-mountable computing device comprises a heat exchanger and one or more fans directing air flow across the heat exchanger, wherein the two or more pumps are in fluid communication with the heat exchanger.

19. A rack-mountable computing device comprising:
a plurality of data processing devices;
a cooling system configured to provide cooling to the plurality of data processing devices via cooling fluid loops, the cooling system comprising a pump assembly configured to mount to the cooling system, the pump assembly comprising:
two or more pumps mounted to the pump assembly;
a fluid inlet connector;
a fluid outlet connector; and
a fluid channel extending from the fluid inlet connector, through each of the two or more pumps in a series connection, and to the fluid outlet connector.

20. The rack-mountable computing device of claim 19, further comprising:
a heat exchanger within the cooling system; and
one or more fans within the cooling system, the one or more fans directing air flow across the heat exchanger, wherein the two or more pumps are in fluid communication with the heat exchanger.
